(19) United States
(12) Patent Application Publication
(10) Pub. No.: US 2019/0334123 A1
(43) Pub. Date: Oct. 31, 2019

(54) PACKAGE STRUCTURE AND PACKAGING METHOD OF OLED DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xingyong ZHANG, Wuhan, Hubei (CN)

(21) Appl. No.: 16/093,978

(22) PCT Filed: Aug. 1, 2018
(86) PCT No.: PCT/CN2018/097840

§ 371 Date: Oct. 16, 2018

(30) Foreign Application Priority Data
Apr. 25, 2018 (CN) 201810378186.2

(51) Int. Cl. H01L 51/52; H01L 51/56

(52) U.S. Cl. CPC H01L 51/5256; H01L 2251/301; H01L 51/56

(57) ABSTRACT

A package structure and a packaging method of an organic light emitting diode (OLED) device of the present invention utilize an organic layer disposed between a first organic reinforcing layer and a second organic reinforcing layer to improve water oxygen barrier performance of the OLED device, and each of the first organic reinforcing layer and the second organic reinforcing layer includes organic fluoride. The organic fluoride combines with silicon dioxide through chemical bonds to render organic and inorganic interface bonding performance superior to simple physical stacking, thereby to extend the lifespan of the OLED device.

### CROSS REFERENCE TO RELATED APPLICATIONS

This application is a U.S. National Phase application submitted under 35 U.S.C. § 371 of Patent Cooperation Treaty Application serial No. PCT/CN2018/097840, filed Aug. 1, 2018, which claims the priority of China Patent Application serial No. 201810378186.2, filed Apr. 25, 2018, the disclosures of which are incorporated herein by reference in their entirety.

### BACKGROUND OF INVENTION

### 1. Field of Invention

The present invention relates to displaying, and particularly to a package structure and packaging method of an OLED device.

### 2. Related Art

Organic light emitting diode (OLED) devices have attracted wide attention due to advantages of being self-luminous, rich colors, quick response times, wide viewing angles, and light weight. However, organic materials used in OLED devices tend to be corroded by water and oxygen, thereby reducing lifespan of the OLED devices. As a result, to efficiently package and improve OLED devices have become a hot study subject in OLED packaging.

Generally, thin film packaging utilizes structure of laminated multi-films to improve water oxygen barrier performance. An organic layer having a greater thickness in the multi-films is configured to buffer stress and to function as a foreign matter coating layer. However, water oxygen barrier performance of the organic layer is worse than that of an inorganic layer, and therefore protection of the organic layer has increasingly got attention of researchers.

Currently, organic materials used in OLED devices are still a big problem that reduces lifespan of OLED devices. Under the premise that certain organic materials that cannot be replaced with inorganic materials, it highlights importance of protecting organic materials.

### SUMMARY OF INVENTION

Accordingly, an object of the present invention is to provide a package structure and packaging method of an organic light emitting diode (OLED) device, which is capable of improving a lifespan of the OLED device through protection of organic materials under the premise that certain organic materials that cannot be replaced with inorganic materials.

A package structure of an organic light emitting diode (OLED) device of the present invention comprises at least a set of thin films packaged on an OLED device to be packaged, the at least a set of thin films comprising a first inorganic layer, a first organic reinforcing layer, an organic layer, a second organic reinforcing layer, and a second inorganic layer laminated on the OLED device to be packaged; wherein each of the first organic reinforcing layer and the second organic reinforcing layer comprises organic fluoride having high temperature resistance and low surface energy performance.

In the package structure of the OLED device of the present invention, the first inorganic layer and the second inorganic layer are made of silicon oxide, silicon nitride, silicon carbon nitride, aluminum oxide, or titanium oxide.

In the package structure of the OLED device of the present invention, the first inorganic layer and the second inorganic layer are made of silicon oxide, and each of the first organic reinforcing layer and the second organic reinforcing layer is an organic fluoride layer.

In the package structure of the OLED device of the present invention, the first inorganic layer and the second inorganic layer are not made of silicon oxide, and each of the first organic reinforcing layer and the second organic reinforcing layer comprises a silicon oxide layer and an organic fluoride layer; wherein in the first organic reinforcing layer, the silicon oxide layer is designated as a first silicon oxide layer, and the organic fluoride layer is designated as a first organic fluoride layer; and wherein in the second organic reinforcing layer, the silicon oxide layer is designated as a second silicon oxide layer, and the organic fluoride layer is designated as a second organic fluoride layer.

In the package structure of the OLED device of the present invention, the first silicon oxide layer is disposed adjacent to the first inorganic layer, and the first organic fluoride layer is disposed adjacent to the organic layer.

In the package structure of the OLED device of the present invention, the second silicon oxide is disposed adjacent to the second inorganic layer, and the second organic fluoride layer is disposed adjacent to the organic layer.

In the package structure of the OLED device of the present invention, each of the first silicon oxide layer and the second silicon oxide layer has a thickness between 0.1 um to 0.2 um, and each of the first organic fluoride layer and the second organic fluoride layer has a thickness between 10 nm to 30 nm.

The present invention further provides a package structure of an organic light emitting diode (OLED) device, comprising at least a set of thin films packaged on an OLED device to be packaged, the at least a set of thin films comprising a first inorganic layer, a first organic reinforcing layer, an organic layer, a second organic reinforcing layer, and a second inorganic layer laminated on the OLED device to be packaged; wherein each of the first organic reinforcing layer and the second organic reinforcing layer comprises organic fluoride.

In the package structure of the OLED device of the present invention, the first inorganic layer and the second inorganic layer are made of silicon oxide, silicon nitride, silicon carbon nitride, aluminum oxide, or titanium oxide.

In the package structure of the OLED device of the present invention, the first inorganic layer and the second inorganic layer are made of silicon oxide, and each of the first organic reinforcing layer and the second organic reinforcing layer is an organic fluoride layer.

In the package structure of the OLED device of the present invention, the first inorganic layer and the second inorganic layer are not made of silicon oxide, and each of the first organic reinforcing layer and the second organic reinforcing layer comprises a silicon oxide layer and an organic fluoride layer; wherein in the first organic reinforcing layer, the silicon oxide layer is designated as a first silicon oxide layer, and the organic fluoride layer is designated as a first organic fluoride layer; and wherein in the second organic reinforcing layer, the silicon oxide layer is designated as a second silicon oxide layer, and the organic fluoride layer is designated as a second organic fluoride layer.

In the package structure of the OLED device of the present invention, the first silicon oxide layer is disposed adjacent to the first inorganic layer, and the first organic fluoride layer is disposed adjacent to the organic layer.

In the package structure of the OLED device of the present invention, the second silicon oxide is disposed adjacent to the second inorganic layer, and the second organic fluoride layer is disposed adjacent to the organic layer.

In the package structure of the OLED device of the present invention, each of the first silicon oxide layer and the second silicon oxide layer has a thickness between 0.1 um to 0.2 um, and each of the first organic fluoride layer and the second organic fluoride layer has a thickness between 10 nm to 30 nm.

The present invention further provides a packaging method of an organic light emitting diode (OLED) device, comprising a step of forming at least a set of thin films on an OLED device to be packaged, the at least a set of thin films comprising a first inorganic layer, a first organic reinforcing layer, an organic layer, a second organic reinforcing layer, and a second inorganic layer laminated on the OLED device to be packaged.

In the packaging method of the OLED device of the present invention, the first inorganic layer and the second inorganic layer are made of silicon oxide, and each of the first organic reinforcing layer and the second organic reinforcing layer is an organic fluoride layer; and the step of forming the at least a set of thin films on the OLED device to be packaged comprises forming the first inorganic layer, first organic reinforcing layer, the organic layer, the second organic reinforcing layer, and the second inorganic layer on the OLED device to be packaged in turn.

In the packaging method of the OLED device of the present invention, the first inorganic layer and the second inorganic layer are not made of silicon oxide, and each of the first organic reinforcing layer and the second organic reinforcing layer comprises a silicon oxide layer and an organic fluoride layer; and the step of forming the at least a set of thin films on the OLED device to be packaged comprises forming the first inorganic layer, first organic reinforcing layer, the organic layer, the second organic reinforcing layer, and the second inorganic layer on the OLED device to be packaged in turn.

The present invention has advantages as follows: the package structure and the packaging method of the OLED device of the present invention utilize the organic layer disposed between the first organic reinforcing layer and the second organic reinforcing layer to improve water oxygen barrier performance of the OLED device, and each of the first organic reinforcing layer and the second organic reinforcing layer comprises organic fluoride. The organic fluoride combines with silicon dioxide through chemical bonds to render organic and inorganic interface bonding performance superior to simple physical stacking, thereby to extend the lifespan of the OLED device.

### BRIEF DESCRIPTION OF DRAWINGS

FIG. 1 is a schematic structural view of a package structure of an OLED device in accordance with an embodiment of the present invention.

FIG. 2 is another schematic structural view of a package structure of an OLED device in accordance with an embodiment of the present invention.

FIG. 3 is a flowchart of a package structure of an OLED device in accordance with an embodiment of the present invention.

FIG. 4 is another flowchart of a package structure of an OLED device in accordance with an embodiment of the present invention.

FIG. 5 is another flowchart of a package structure of an OLED device in accordance with an embodiment of the present invention.

### DESCRIPTION OF PREFERRED EMBODIMENTS

Please refer to FIG. 1 showing a schematic structural view of a package structure of an OLED device in accordance with an embodiment of the present invention. As shown in FIG. 1, the present inventio provides a package structure of an OLED device. The package structure comprises at least a set of thin films packaged on an OLED device 101 to be packaged. The at least a set of thin films comprising a first inorganic layer 102, a first organic reinforcing layer 103, an organic layer 104, a second organic reinforcing layer 105, and a second inorganic layer 106 laminated on the OLED device 101 to be packaged.

Each of the first organic reinforcing layer 103 and the second organic reinforcing layer 105 comprises organic fluoride. Particularly, each of the first organic reinforcing layer 103 and the second organic reinforcing layer 105 comprises organic fluoride having the advantages of high temperature resistance and low surface energy performance, wherein the low surface energy performance is capable of reaching as low as 16 mN/m, and the organic fluoride is a material having the lowest surface energy performance among current organic materials. The organic material can be tightly combined with silicon oxide through chemical bonds to improve organic and inorganic interfacial properties and water and oxygen resistance of organic materials.

In an embodiment of the present invention, the first inorganic layer 102 and the second inorganic layer 106 are made of silicon oxide, silicon nitride, silicon carbon nitride, aluminum oxide, or titanium oxide. By utilizing an inorganic functional material of silicon oxide, silicon nitride, silicon carbon nitride, aluminum oxide, or titanium oxide for improving water and oxygen resistance, the package structure of the OLED device has a better performance of water and oxygen resistance, thereby to extend a lifespan of the OLED device.

Specifically, in case the first inorganic layer 102 and the second inorganic layer 106 are made of silicon oxide, each of the first organic reinforcing layer 103 and the second organic reinforcing layer 105 is an organic fluoride layer. Namely, the first organic reinforcing layer 103 and the second organic reinforcing layer 105 utilize their innate quality to improve the package structure of the OLED device. Additionally, the first organic reinforcing layer 103 is capable of being tightly combined with the first inorganic layer 102 through chemical bonds. Likewise, the second organic reinforcing layer 105 is capable of being tightly combined with the second inorganic layer 106 through chemical bonds.

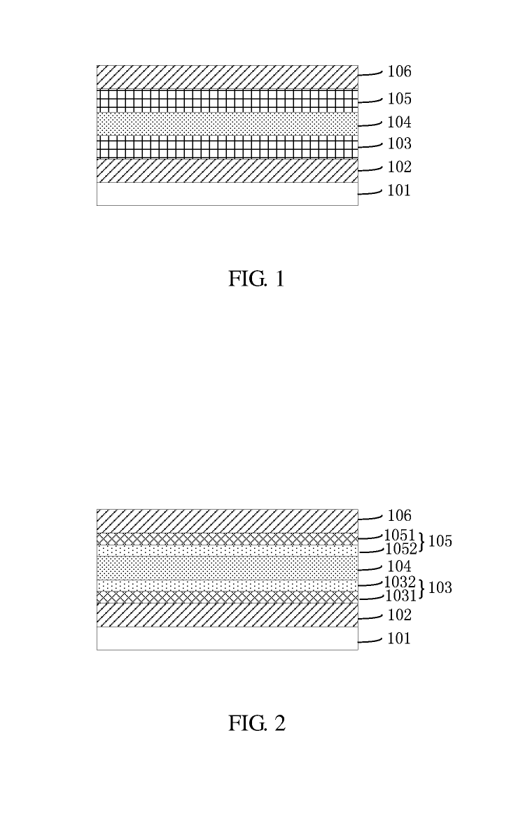

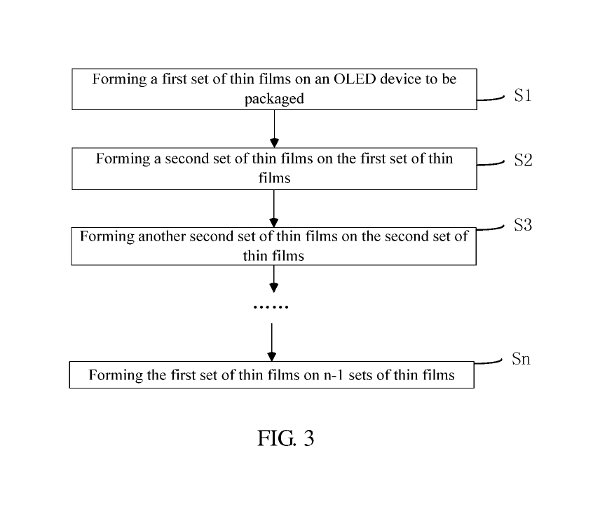

Please refer to FIG. 2 showing another schematic structural view of a package structure of an OLED device in accordance with an embodiment of the present invention. As shown in FIG. 2, in case the first inorganic layer 102 and the second inorganic layer 106 are not made of silicon oxide, each of the first organic reinforcing layer 103 and the second organic reinforcing layer 105 comprises a silicon oxide layer and an organic fluoride layer; wherein in the first organic reinforcing layer 103, the silicon oxide layer is designated as a first silicon oxide layer 1031, and the organic fluoride layer is designated as a first organic fluoride layer 1032; and wherein in the second organic reinforcing layer 105, the silicon oxide layer is designated as a second silicon oxide layer 1051, and the organic fluoride layer is designated as a second organic fluoride layer 1052. Particularly, the first silicon oxide layer 1031 and the second silicon oxide layer 1051 are made of silicon oxide, and the first organic fluoride layer 1032 and the second organic fluoride layer 1052 are made of organic fluoride. Namely, the first organic reinforcing layer 103 and the second organic reinforcing layer 105 utilize their innate quality to improve the package structure of the OLED device. Furthermore, the first organic reinforcing layer 103 is capable of being tightly combined with the second organic reinforcing layer 105 through chemical bonds between the silicon oxide layer and the organic fluoride layer.

Specifically, in the first organic reinforcing layer 103, the silicon oxide layer is disposed adjacent to the first inorganic layer, and the organic fluoride layer is disposed adjacent to the organic layer. Namely, the first silicon oxide layer 1031 is disposed adjacent to the first inorganic layer 102, and the first organic fluoride layer 1032 is disposed adjacent to the organic layer 104. In the second organic reinforcing layer 105, the silicon oxide is disposed adjacent to the second inorganic layer, and the organic fluoride layer is disposed adjacent to the organic layer. Namely, the second silicon oxide layer 1051 is disposed adjacent to the second inorganic layer 106, and the second organic fluoride layer 1052 is disposed adjacent to the organic layer 104. Namely, in the package structure of the OLED device, the first inorganic layer 102, the first silicon oxide layer 1031, the first organic fluoride layer 1032, the organic layer 104, the second organic fluoride layer 1052, the second silicon oxide layer 1051, and the inorganic layer 106 are laminated in order on the OLED device 101 to be packaged. Furthermore, each of the first silicon oxide layer 1031 and the second silicon oxide layer 1051 has a thickness between 0.1 um to 0.2 um, and each of the first organic fluoride layer 1032 and the second organic fluoride layer 1052 has a thickness between 10 nm to 30 nm.

The package structure of the OLED device of the present invention utilizes the organic layer disposed between the first organic reinforcing layer and the second organic reinforcing layer to improve water oxygen barrier performance of the OLED device, and each of the first organic reinforcing layer and the second organic reinforcing layer comprises organic fluoride. The organic fluoride combines with silicon dioxide through chemical bonds to render organic and inorganic interface bonding performance superior to simple physical stacking, thereby to extend the lifespan of the OLED device.

A packaging method of the OLED device of the present invention comprises a step of forming at least a set of thin films on an OLED device to be packaged. The at least a set of thin films comprises a first inorganic layer, a first organic reinforcing layer, an organic layer, a second organic reinforcing layer, and a second inorganic layer laminated on the OLED device to be packaged. Each of the first organic reinforcing layer and the second organic reinforcing layer comprises organic fluoride. The first inorganic layer and the second inorganic layer are made of silicon oxide, silicon nitride, silicon carbon nitride, aluminum oxide, or titanium oxide. By utilizing an inorganic functional material of silicon oxide, silicon nitride, silicon carbon nitride, aluminum oxide, or titanium oxide for improving water and oxygen resistance, the package structure of the OLED device has a better performance of water and oxygen resistance, thereby to extend a lifespan of the OLED device.

For instance, please refer to FIG. 3 showing a flowchart of a package structure of an OLED device in accordance with an embodiment of the present invention. As shown in FIG. 3, step S1, forming a first set of thin films on an OLED device to be packaged; step S2, forming a second set of thin films on the first set of thin films; step S3, forming a third set of thin films on the second set of thin films; . . . ; step Sn, forming an n set of thin films on n−1 sets of thin films. Of particular note is that the number of the set of thin films is varied subject to practical requirements and is not limited thereby.

In case the first inorganic layer and the second inorganic layer are made of silicon oxide, each of the first organic reinforcing layer and the second organic reinforcing layer is an organic fluoride layer. The forming at least a set of thin films on an OLED device to be packaged comprises: forming a first inorganic layer, a first organic fluoride layer, an organic layer, a second organic fluoride layer, and a second inorganic layer on the OLED device to be packaged in turn. Particularly, the first organic fluoride layer and the second organic fluoride layer are made of organic fluoride.

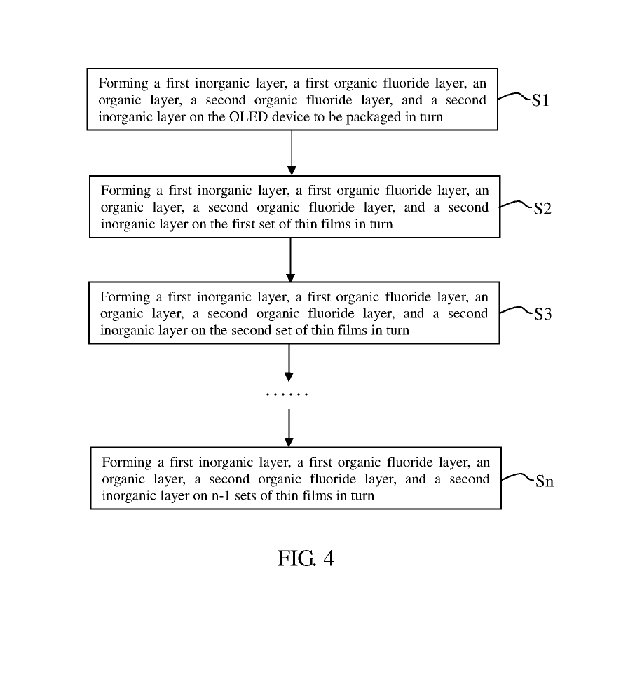

For instance, please refer to FIG. 4 showing another schematic flowchart of a package structure of an OLED device in accordance with an embodiment of the present invention. As shown in FIG. 4, step S1, form a first inorganic layer, a first organic fluoride layer, an organic layer, a second organic fluoride layer, and a second inorganic layer on the OLED device to be packaged in turn; step S2, form a first inorganic layer, a first organic fluoride layer, an organic layer, a second organic fluoride layer, and a second inorganic layer on the first set of thin films in turn; step S3, form a first inorganic layer, a first organic fluoride layer, an organic layer, a second organic fluoride layer, and a second inorganic layer on the second set of thin films in turn; . . . ; step Sn, form a first inorganic layer, a first organic fluoride layer, an organic layer, a second organic fluoride layer, and a second inorganic layer on n−1 sets of thin films in turn. Of particular note is that the number of the set of thin films is varied subject to practical requirements and is not limited thereby.

In case the first inorganic layer and the second inorganic layer are not made of silicon oxide, each of the first organic reinforcing layer and the second organic reinforcing layer comprises a silicon oxide layer and an organic fluoride layer. The forming at least a set of thin films on an OLED device to be packaged comprises: forming a first inorganic layer, a first silicon oxide layer, a first organic fluoride layer, an organic layer, a second organic fluoride layer, a second silicon oxide layer, and a second inorganic layer on the OLED device to be packaged in turn.

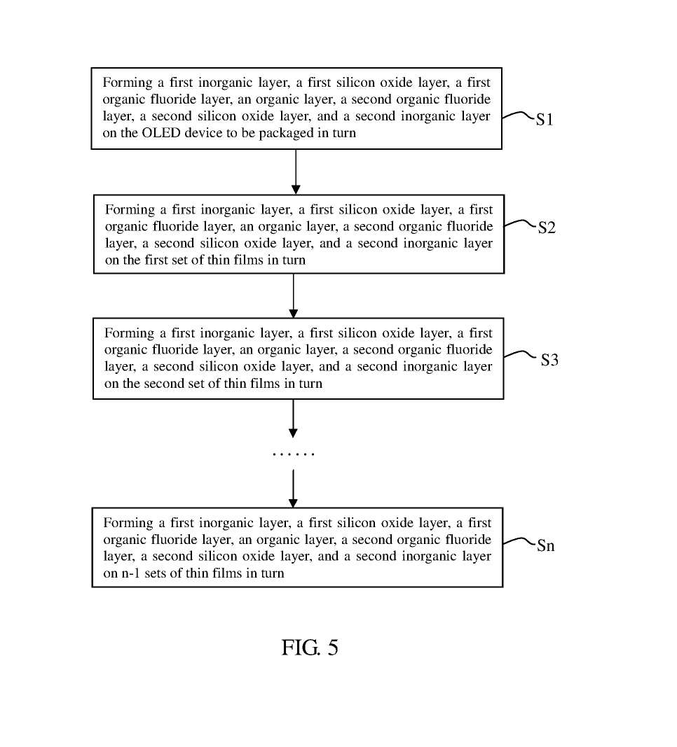

For instance, please refer to FIG. 5 showing another schematic flowchart of a package structure of an OLED device in accordance with an embodiment of the present invention. As shown in FIG. 5, step S1, form a first inorganic layer, a first silicon oxide layer, a first organic fluoride layer, an organic layer, a second organic fluoride layer, a second silicon oxide layer, and a second inorganic layer on the OLED device to be packaged in turn; step S2, form a first inorganic layer, a first silicon oxide layer, a first organic fluoride layer, an organic layer, a second organic fluoride layer, a second silicon oxide layer, and a second inorganic layer on the first set of thin films in turn; step S3, form a first inorganic layer, a first silicon oxide layer, a first organic fluoride layer, an organic layer, a second organic fluoride layer, a second silicon oxide layer, and a second inorganic layer on the second set of thin films in turn; . . . ; step Sn, form a first inorganic layer, a first silicon oxide layer, a first organic fluoride layer, an organic layer, a second organic fluoride layer, a second silicon oxide layer, and a second inorganic layer on n−1 sets of thin films in turn. Of particular note is that the number of the set of thin films is varied subject to practical requirements and is not limited thereby.

Of particular note is that the package structure formed by the packaging method of the OLED device of the embodiment of the present invention is the same as the package structure of the OLED device as described in previous embodiments and its detailed structured is not repeatedly stated herein.

It is understood that the invention may be embodied in other forms within the scope of the claims. Thus the present examples and embodiments are to be considered in all respects as illustrative, and not restrictive, of the invention defined by the claims.

What is claimed is:

1. A package structure of an organic light emitting diode (OLED) device, comprising:
at least a set of thin films packaged on an OLED device to be packaged, the at least a set of thin films comprising a first inorganic layer, a first organic reinforcing layer, an organic layer, a second organic reinforcing layer, and a second inorganic layer laminated on the OLED device to be packaged;
wherein each of the first organic reinforcing layer and the second organic reinforcing layer comprises organic fluoride having high temperature resistance and low surface energy performance.

2. The package structure of the OLED device of claim 1, wherein the first inorganic layer and the second inorganic layer are made of silicon oxide, silicon nitride, silicon carbon nitride, aluminum oxide, or titanium oxide.

3. The package structure of the OLED device of claim 2, wherein the first inorganic layer and the second inorganic layer are made of silicon oxide, and each of the first organic reinforcing layer and the second organic reinforcing layer is an organic fluoride layer.

4. The package structure of the OLED device of claim 2, wherein the first inorganic layer and the second inorganic layer are not made of silicon oxide, and each of the first organic reinforcing layer and the second organic reinforcing layer comprises a silicon oxide layer and an organic fluoride layer; wherein in the first organic reinforcing layer, the silicon oxide layer is designated as a first silicon oxide layer, and the organic fluoride layer is designated as a first organic fluoride layer; and wherein in the second organic reinforcing layer, the silicon oxide layer is designated as a second silicon oxide layer, and the organic fluoride layer is designated as a second organic fluoride layer.

5. The package structure of the OLED device of claim 4, wherein the first silicon oxide layer is disposed adjacent to the first inorganic layer, and the first organic fluoride layer is disposed adjacent to the organic layer.

6. The package structure of the OLED device of claim 4, wherein the second silicon oxide is disposed adjacent to the second inorganic layer, and the second organic fluoride layer is disposed adjacent to the organic layer.

7. The package structure of the OLED device of claim 4, wherein each of the first silicon oxide layer and the second silicon oxide layer has a thickness between 0.1 um to 0.2 um, and each of the first organic fluoride layer and the second organic fluoride layer has a thickness between 10 nm to 30 nm.

8. A package structure of an organic light emitting diode (OLED) device, comprising at least a set of thin films packaged on an OLED device to be packaged, the at least a set of thin films comprising a first inorganic layer, a first organic reinforcing layer, an organic layer, a second organic reinforcing layer, and a second inorganic layer laminated on the OLED device to be packaged;
wherein each of the first organic reinforcing layer and the second organic reinforcing layer comprises organic fluoride.

9. The package structure of the OLED device of claim 8, wherein the first inorganic layer and the second inorganic layer are made of silicon oxide, silicon nitride, silicon carbon nitride, aluminum oxide, or titanium oxide.

10. The package structure of the OLED device of claim 9, wherein the first inorganic layer and the second inorganic layer are made of silicon oxide, and each of the first organic reinforcing layer and the second organic reinforcing layer is an organic fluoride layer.

11. The package structure of the OLED device of claim 9, wherein the first inorganic layer and the second inorganic layer are not made of silicon oxide, and each of the first organic reinforcing layer and the second organic reinforcing layer comprises a silicon oxide layer and an organic fluoride layer; wherein in the first organic reinforcing layer, the silicon oxide layer is designated as a first silicon oxide layer, and the organic fluoride layer is designated as a first organic fluoride layer; and
wherein in the second organic reinforcing layer, the silicon oxide layer is designated as a second silicon oxide layer, and the organic fluoride layer is designated as a second organic fluoride layer.

12. The package structure of the OLED device of claim 11, wherein the first silicon oxide layer is disposed adjacent to the first inorganic layer, and the first organic fluoride layer is disposed adjacent to the organic layer.

13. The package structure of the OLED device of claim 11, wherein the second silicon oxide is disposed adjacent to the second inorganic layer, and the second organic fluoride layer is disposed adjacent to the organic layer.

14. The package structure of the OLED device of claim 11, wherein each of the first silicon oxide layer and the second silicon oxide layer has a thickness between 0.1 um to 0.2 um, and each of the first organic fluoride layer and the second organic fluoride layer has a thickness between 10 nm to 30 nm.

15. A packaging method of an organic light emitting diode (OLED) device, comprising a step of:
forming at least a set of thin films on an OLED device to be packaged, the at least a set of thin films comprising a first inorganic layer, a first organic reinforcing layer, an organic layer, a second organic reinforcing layer, and a second inorganic layer laminated on the OLED device to be packaged;
wherein each of the first organic reinforcing layer and the second organic reinforcing layer comprises organic fluoride.

16. The packaging method of the OLED device of claim 15, wherein the first inorganic layer and the second inorganic layer are made of silicon oxide, and each of the first organic reinforcing layer and the second organic reinforcing layer is an organic fluoride layer; and the step of forming the at least a set of thin films on the OLED device to be packaged comprises:
forming the first inorganic layer, first organic reinforcing layer, the organic layer, the second organic reinforcing layer, and the second inorganic layer on the OLED device to be packaged in turn.

17. The packaging method of the OLED device of claim 15, wherein the first inorganic layer and the second inorganic layer are not made of silicon oxide, and each of the first organic reinforcing layer and the second organic reinforcing layer comprises a silicon oxide layer and an organic fluoride layer; and the step of forming the at least a set of thin films on the OLED device to be packaged comprises:
forming the first inorganic layer, first organic reinforcing layer, the organic layer, the second organic reinforcing layer, and the second inorganic layer on the OLED device to be packaged in turn.
